(19) United States
(12) Patent Application Publication
(10) Pub. No.: US 2008/0017998 A1
(43) Pub. Date: Jan. 24, 2008

(54) SEMICONDUCTOR COMPONENT AND METHOD OF MANUFACTURE

(76) Inventor: Jeanne S. Pavio, Paradise Valley, AZ (US)

Correspondence Address: HVVI SEMICONDUCTORS, INC., c/o PORTFOLIOIP, P.O. BOX 52050, MINNEAPOLIS, MN, 55402, US

(21) Appl. No.: 11/458,566

(22) Filed: Jul. 19, 2006

(51) Int. Cl. H01L 23/28

(52) U.S. Cl. 257/787

(57) ABSTRACT

In various embodiments, semiconductor components and methods to manufacture semiconductor components are disclosed. In one embodiment, a semiconductor component includes a semiconductor die and multiple coplanar leads coupled to the semiconductor die, wherein the semiconductor die includes a power transistor and wherein the multiple leads are spaced apart from each other by a distance of about 0.1 millimeters (mm) or less. The semiconductor components further include a packaging material encapsulating the semiconductor die, wherein the packaging material is formed between the leads to electrically isolate the leads from each other. Other embodiments are described and claimed.

### FIELD OF THE INVENTION

Embodiments of the present invention relates generally to semiconductor technology, and more specifically to semiconductor components and methods of their manufacture.

### BACKGROUND OF THE INVENTION

Semiconductor component manufacturers are constantly striving to increase the performance of their products, while decreasing their cost of manufacture. A cost intensive area in the manufacture of semiconductor components is packaging of a semiconductor die. As those skilled in the art are aware, semiconductor die are fabricated in wafers, which may then be singulated or diced. One or more semiconductor die may be placed in a package to protect them from environmental and physical stresses.

Packaging semiconductor die may increase the cost and complexity of manufacturing semiconductor components because the packaging designs typically include several features such as, for example, providing protection, permitting transmission of electrical signals to and from the semiconductor die, and providing for removal of heat generated by the semiconductor die during operation.

Accordingly, it would be desirable to have a semiconductor package for dissipating heat from a semiconductor die and a method for manufacturing the semiconductor package that is cost efficient.

### BRIEF DESCRIPTION OF THE DRAWINGS

FIG. 1 is a cross sectional view of a semiconductor component in accordance with an embodiment of the present invention;

FIG. 2 is top view of a portion of a leadframe during an initial stage of manufacturing in accordance with an embodiment of the present invention;

FIG. 3 is an isometric view of a portion of the leadframe of FIG. 2 at a later stage of manufacturing in accordance with an embodiment of the present invention;

FIG. 4 is a top view of a portion of the leadframe shown in FIG. 3 at a later stage of assembly in accordance with an embodiment of the present invention;

FIG. 5 is a top view of a portion of the leadframe shown in FIG. 4 at a later stage of assembly in accordance with an embodiment of the present invention;

FIG. 6 is a flow diagram of a method to manufacture semiconductor components in accordance with an embodiment of the present invention;

FIG. 7 is a cross sectional view of a semiconductor component in accordance with an embodiment of the present invention;

FIG. 8 is a top view of a portion of a leadframe during assembly in accordance with an embodiment of the present invention;

FIG. 9 is a top view of a portion of the leadframe of FIG. 8 at a later stage of assembly in accordance with an embodiment of the present invention;

FIG. 10 is a cross-sectional view of a semiconductor component in accordance with an embodiment of the present invention;

FIG. 11 is a top view of a portion of a leadframe during assembly in accordance with an embodiment of the present invention;

FIG. 12 is a top view of a portion of the leadframe of FIG. 11 at a later stage of assembly in accordance with an embodiment of the present invention; and

FIG. 13 is top view of a portion of a leadframe during assembly in accordance with an embodiment of the present invention.

### DETAILED DESCRIPTION OF THE DRAWINGS

For ease of understanding, elements in the figures are not necessarily drawn to scale, and like reference numbers are used where appropriate throughout the various figures.

In the following detailed description, numerous specific details are set forth in order to provide a thorough understanding of the present invention. However, it will be understood by those skilled in the art that the present invention may be practiced without these specific details. In other instances, well-known methods, procedures, components and circuits have not been described in detail so as not to obscure the present invention. The following detailed description is merely exemplary in nature and is not intended to limit the disclosure of this document and uses of the disclosed embodiments. Furthermore, there is no intention to be bound by any expressed or implied theory presented in the preceding text, including the title, technical field, background, or the following abstract.

In the following description and claims, the terms “comprise” and “include,” along with their derivatives, may be used and are intended as synonyms for each other. In addition, in the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. For example, “coupled” may be that two or more elements do not contact each other but are joined together via a third element.

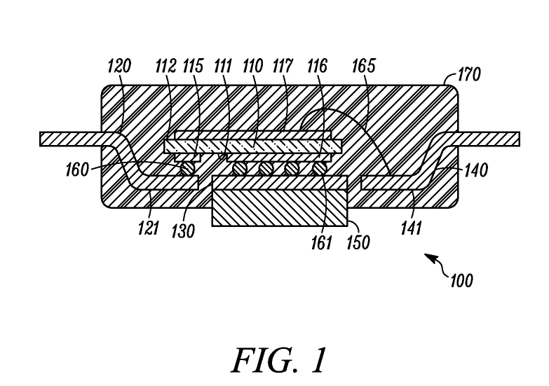

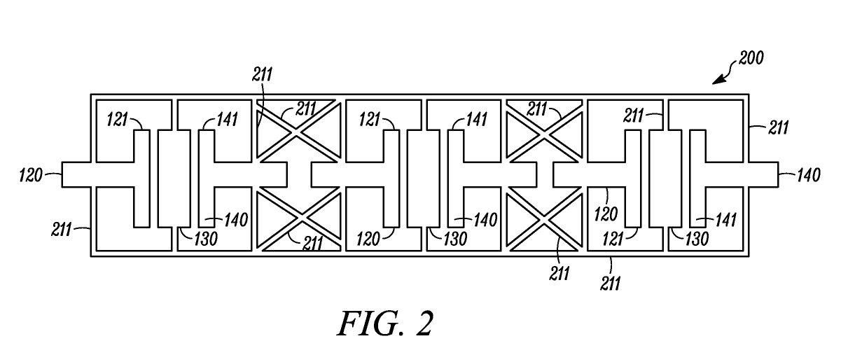

FIG. 1 is a cross-sectional view of a semiconductor component 100 in accordance with an embodiment of the present invention. Various methods for making semiconductor component 100 are discussed below with reference to FIGS. 2 to 6.

In some embodiments, semiconductor component 100 includes a semiconductor die 110, a gate lead 120, a source lead 130, a drain lead 140, and a heat sink 150. Heat sink 150 is coupled to a bottom surface of source lead 130.

Semiconductor die 110 may be coupled to a top surface of source lead 130. Semiconductor die 110 includes surfaces 111 and 112 and further includes a gate interconnect 115 on surface 111, a source interconnect 116 on surface 111, and a drain interconnect 117 on surface 112. Interconnects 115, 116, and 117 may be comprise an electrically and thermally conductive material such as, for example, a metal or metal alloy. In some embodiments, interconnects 115, 116, and 117 may comprise copper.

Gate lead 120 is coupled to gate interconnect 115 via a wafer bump 160, source lead 130 is coupled to source interconnect 116 via wafer bumps 161, and drain lead 140 is coupled to drain interconnect 117 via a wirebond 165. Wafer bumps 160 and 161 may be gold-tin (AuSn) wafer bumps.

In some embodiments, component 100 is discrete device or discrete component, wherein semiconductor die 110 comprises a discrete semiconductor device such as, for example, a discrete power transistor, although the scope of the present invention is not limited in this respect. A power transistor is a device that may be capable of handling at least one ampere of electrical current. In addition a power transistor is a device that can be coupled to relatively large operating voltage potentials of, for example, at least about 20 volts to over 100 volts, and may be used in power amplifiers to generate at least about one watt of output power.

Although the scope of the present invention is not limited in this respect, in some embodiments, semiconductor die 110 is a radio frequency (RF) power transistor constructed to operate at frequencies greater than about 50 megahertz (MHz) and to have a power output greater than about one watt. RF power transistors can be used in RF power amplifiers that may be used in wireless communications applications such as, for example, cellular base stations, high frequency (HF), very high frequency (VHF) and ultra high frequency (UHF) broadcast transmitters, and microwave radar and avionics systems. Some RF power amplifiers (RFPAs) provide from about five watts (W) to more than about 200 W of output power. In one embodiment, semiconductor die 110 is a RF power transistor adapted to operate at frequencies greater than about 500 megahertz (MHz) and has an output power greater than about five watts.

Further, in some embodiments, the power transistor of semiconductor die 110 comprises one or more vertical power transistor structures such as, for example, vertical metal oxide semiconductor field effect transistors (MOSFETs) or vertical bipolar power transistors. In the embodiments wherein semiconductor die 110 includes vertical MOSFETs, these vertical MOSFETs each have a source region, a drain region, and a gate. The vertical power transistor is vertical in that the source region and the drain region, or source interconnect and drain interconnect, are at or adjacent opposite surfaces of semiconductor die 110. The source and drain interconnects may also be referred to as source and drain electrodes. The gate of a vertical power transistor may be formed at the same surface of die 110 as the source region or interconnect of the vertical power transistor. During operation, the electrical current flow from the source region to the drain region in a vertical power transistor may be substantially perpendicular to the semiconductor die surfaces. In other words, current flows essentially vertically through a vertical MOSFET from a source region or interconnect located adjacent one surface of semiconductor die 110 to a drain region or interconnect located adjacent to the opposite surface of semiconductor die 110. An example of a vertical power transistor is described in U.S. patent application Ser. No. 10/557,135, entitled “POWER SEMICONDUCTOR DEVICE AND METHOD THEREFOR,” filed Nov. 17, 2005, which claims priority to Patent Cooperation Treaty (PCT) International Application Number PCT/US2005/000205 entitled “POWER SEMICONDUCTOR DEVICE AND METHOD THEREFOR,” having an International Filing Date of Jan. 6, 2005 and an International Publication Date of Jul. 28, 2005, the contents of both of these patent applications are incorporated herein by reference in their entirety.

In other embodiments, the transistors in semiconductor die 110 may be vertical bipolar transistors such as insulated gate bipolar transistors (IGBTs). In such embodiments, one side of semiconductor die 110 may have an emitter region and a base region. The other side of the die may have a collector region.

Although semiconductor die 110 is described as including vertical transistors in some embodiments, this is not a limitation of the present invention. In alternate embodiments, semiconductor die 110 may include lateral transistor structures such as, for example, a laterally diffused metal-oxide-semiconductor (LDMOS) transistor structure. In an LDMOS power transistor, the gate, source region, and the drain region are located adjacent the same surface of a semiconductor die and electrical current flows laterally through the transistor between the source and drain regions of the LDMOS power transistor.

Vertical MOSFET devices may have some advantages over lateral transistors such as LDMOS devices. For example, the transistor cells in a vertical device may be relatively smaller and denser than the transistor cells in an LDMOS device, since the source region and the drain region in a vertical device are at opposite sides of the semiconductor die. Consequently, a vertical device may have a lower “on” resistance than an LDMOS device.

The power transistor of semiconductor die 110 may have three electrodes or interconnects such as, for example, interconnects 115, 116, and 117. The power transistor of semiconductor die 110 may be a discrete field-effect transistor (FET), wherein interconnects 115, 116, and 117 are respectively coupled to a gate region, a source region, and a drain region of the power transistor. Accordingly, in this embodiment, gate lead 120 is coupled to the gate region of semiconductor die 110 via gate interconnect 115; source lead 130 is coupled to the source region of semiconductor die 110 via source interconnect 116; and drain lead 140 is coupled to the drain region of semiconductor die 110 via drain interconnect 117. As may be appreciated, electrical current may flow between source lead 130 and drain lead 140 by applying a voltage to gate lead 120.

Although semiconductor die 110 has been described as a discrete power transistor, this is not a limitation of the present invention. In alternate embodiments, semiconductor die 110 may comprise a small-signal transistor. A small-signal transistor typically controls relatively small currents, for example, less than about one ampere of current, and dissipate less than about one watt of power.

Although semiconductor die 110 is described as comprising a FET device, this is not a limitation of the present invention. In alternate embodiments, semiconductor die may include a bipolar transistor. Further, in alternate embodiments, semiconductor die 110 and/or semiconductor component 100 may be an integrated component or integrated circuit (IC) rather than a discrete device or discrete component. For example, semiconductor die 110 may be an integrated circuit having high density digital logic and a power device integrated together on the same die. In addition, semiconductor component 100 may be an integrated component including more than one semiconductor die. In the example wherein semiconductor die 110 is an IC, semiconductor component 100 may have more than the three leads shown in the cross section of FIG. 1.

Semiconductor component 100 may further include a packaging material 170 such as, for example, a plastic packaging material or other organic material such as a glob top material, that encapsulates semiconductor die 110, source lead 130, a portion of gate lead 120, a portion of drain lead 140, and a portion of heat sink 150. A portion of gate lead 120 is partially exposed external to semiconductor component 100 to provide electrical coupling of an external bias signal (not shown) such as, for example, a voltage ranging from about one to about four volts, to the gate electrode from an external source (not shown); a portion of drain lead 140 is partially exposed external to semiconductor component 100 to provide electrical coupling of an external bias signal such as, for example, a voltage ranging from about 20 volts to about 100 volts, to the drain region of semiconductor die 110 from an external source; and heat sink 150 is partially exposed external to semiconductor component 100 to provide electrical coupling of an external bias signal such as, for example, ground potential, to the source region of semiconductor die 110 from an external source.

Leads 120, 130, and 140 are electrically isolated from each other by packaging material 170. In the embodiment illustrated in FIG. 1, packaging material 170 is formed between gate lead 120 and source lead 130 and between source lead 130 and drain lead 140. The distance between the leads may be determined by the die size. For example, the spacing of the interconnects of semiconductor die 110 may determine how much spacing is needed between the leads of semiconductor component 100. In some embodiments, the distance between gate lead 120 and source lead 130 is less than about 0.1 millimeters (mm) and the distance between source lead 130 and drain lead 140 is less than about 0.1 millimeters (mm). In one embodiment, the distance between gate lead 120 and source lead 130 is about 0.025 millimeters (mm) and the distance between source lead 130 and drain lead 140 is about 0.025 millimeters (mm).

In some embodiments, the leads of semiconductor component 100 may be formed from the same material, and may be formed so that portions of the leads are substantially coplanar to each other. For example, a portion 121 of gate lead 120 is substantially coplanar to source lead 130. In the embodiment illustrated in FIG. 1, a top surface of portion 121 of gate lead 120 is substantially coplanar to a top surface of source lead 130. Further, a portion 141 of drain lead 140 is substantially coplanar to source lead 130 so that a top surface of portion 141 of drain lead 140 is substantially coplanar to a top surface of source lead 130.

Having coplanar leads may be advantageous compared to other package configurations. For example, the substantially coplanar leads of semiconductor component 100 as is illustrated in FIG. 1 provides a relatively simple and cost effective solution to couple portions of semiconductor die 110 to the leads of semiconductor component 100. As will be discussed below, in some embodiments, wafer bumps may be formed on semiconductor die 110 and then die 110 may be attached to the coplanar portions of leads 120 and 130 without the use of wirebonds.

In addition, this type of package configuration may provide performance advantages, such as providing a relatively low resistance thermal path (for example, a thermal path formed by source lead 130 and heat sink 150) to remove heat generated by semiconductor die 110. Further, by not using wirebonds to couple the gate and source regions to leads 120 and 130 this may reduce parasitic resistance, capacitance, and inductance which may be beneficial for electrical and thermal performance.

Turning to FIGS. 2 to 6, various embodiments for manufacturing a semiconductor component, such as, for example, semiconductor component 100 (FIG. 1) are discussed. FIG. 2 is top view of a portion of a leadframe 200 during an initial stage of manufacturing in accordance with an embodiment of the present invention.

Leadframe 200 may be formed by etching an electrically and thermally conductive material, such as, for example, a metal substrate or alloy. In some embodiments, leadframe 200 may comprise copper. Leadframe 200 may include coplanar, spaced apart leads 120, 130 and 140 that are formed at substantially the same time with a single etching step. Leads may also be referred to as pads. In addition, leadframe 200 may include a plurality of support structures 211 to couple the leads of leadframe 200 to each other during assembly of multiple semiconductor components. As will be discussed below, in some embodiments, leadframe 200 may be singulated after the encapsulation of multiple semiconductor components. Support structures 211 may also be referred to as bars, rails, or tie bars.

In some embodiments, the length and the width of portion 121 of the gate lead 120 is about 0.25 inches (about 6.35 millimeters) and about 0.035 inches (about 0.89 millimeters), respectively. Similarly, the length and the width of portion 141 of the drain lead 140 is about 0.25 inches (about 6.35 millimeters) and about 0.035 inches (about 0.89 millimeters), respectively. The length and the width of source lead 130 is about 0.25 inches (about 6.35 millimeters) and about 0.092 inches (about 2.34 millimeters), respectively. The thickness of leads 120, 130, and 140 is about 0.004 inches (about 0.1 millimeters). The distance between gate lead 120 and source lead 130 is less than about 0.004 inches (about 0.1 millimeters) and the distance between source lead 130 and drain lead 140 is less than about 0.004 inches (about 0.1 millimeters).

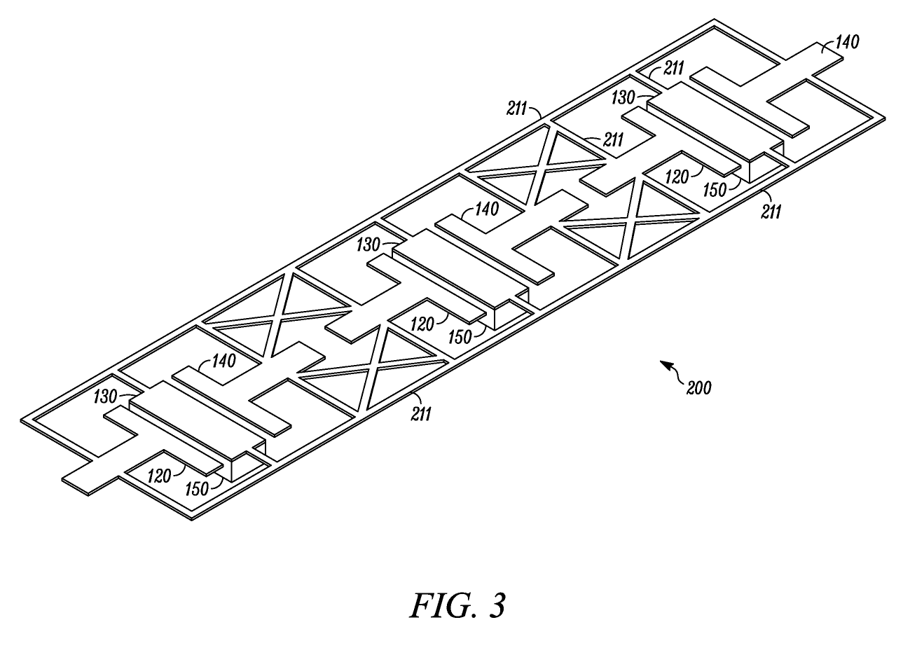

FIG. 3 is an isometric view of a portion of leadframe 200 at a later stage of manufacturing in accordance with an embodiment of the present invention.

FIG. 3 shows heat sinks 150 coupled to the bottom surface of source pads 130. Heat sinks 150 are attached to some, but not all of the leads of leadframe 200 at substantially the same time in a single step.

In some embodiments, heat sinks 150 are attached to each of the source leads of leadframe 200 in a batch operation using brazing. Heat sinks 150 may be brazed to source leads 130 using a thermally and electrically conductive material such as, for example, a material comprising copper or silver such as a copper-silver braze. Heat sinks 150 may also be referred to as thermal pads, thermal slugs, or heat spreaders. Heat sinks 150 provide a structure to remove heat generated by semiconductor die coupled to the heat sinks. For example, in the embodiments wherein semiconductor die comprises a RF power transistor, a heat sink may be needed to remove the heat generated by the RF power transistor. Transferring heat efficiently allows an electrical device or component to operate at cooler temperatures, which may improve performance and reliability.

Prior to attaching heat sinks 150 to source leads 130, heat sinks 150 may be formed by performing a stamping operation, wherein the stamping operation comprises stamping an electrically and thermally conductive material such as, for example, copper or a copper alloy. The stamping operation may further include forming a burr on a portion of each heat sink to provide a mold lock to increase pull-out resistance of heat sinks 150 after forming the packaging material over a portion of heat sinks 150 as is described below.

Attaching a group of heat sinks 150 to source pads 130 simultaneously in a single step operation is advantageous in that it enables a relatively high-volume and cost effective manufacturing process compared to manufacturing techniques for assembling a semiconductor component that include attaching heat sinks to source pads in a serial fashion.

Prior to the attaching of semiconductor die 110 to leadframe 200, leadframe 200 including the attached heat sinks 150 are plated using nickel palladium (NiPd) with a “flash” of gold (Au) or silver (Ag), or may be tin (Sn) plated. For example, leadframe 200 may be plated using NiPd, and then, to prevent oxidizing of NiPd, leadframe 200 may be further plated using a relatively thin layer of gold (Au) or silver (Ag), or may be plated with tin (Sn) directly. As an example, the thickness of the relatively thin layer of plating material may be about 30 microns or less.

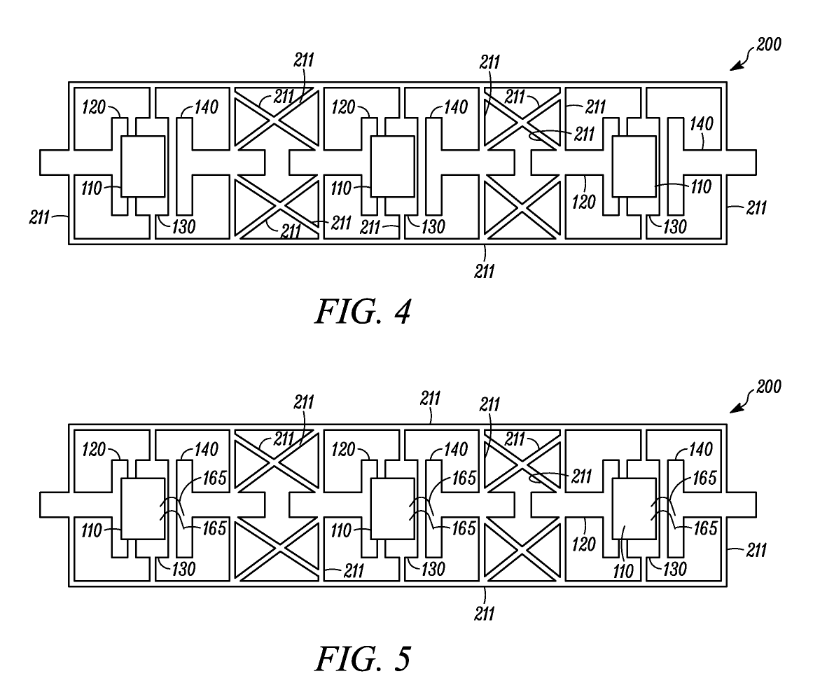

FIG. 4 is a top view of a portion of leadframe 200 at a later stage of assembly in accordance with an embodiment of the present invention. In some embodiments, a number of semiconductor die 110 are coupled to some, but not all of the leads of leadframe 200 prior to encapsulating the semiconductor die and a portion of leadframe 200 using a packaging material.

Although not shown in FIG. 4, gold-tin (AuSn) wafer bumps 160 and 161 (FIG. 1) are formed on a bottom surface of semiconductor die 110. Solder paste may be printed on the leadframe 200 or transfer stamped onto the wafer bumps. Heat may be applied to the assembly to reflow the connection during placement or mounting of the die on the leadframe. For example, leadframe 200 may be mass reflowed in a standard reflow oven.

In some embodiments, semiconductor die 110 is attached to the top surfaces of gate lead 120 and source lead 130. Accordingly, semiconductor die 110 overlies at least two leads in some embodiments, wherein, at least one of the two leads provides a relatively low resistance thermal path to remove heat generated by the die. Since the leads of leadframe 200 are formed from the same, single piece of material, and the tie bars 211 remain in place during the placement of the die, this leadframe structure provides coplanar leads during assembly which can provide a reliable structure for coupling the die to the leads.

FIG. 5 is a top view of a portion of leadframe 200 at a later stage of assembly in accordance with an embodiment of the present invention. In some embodiments, one or more wirebonds 165 may be used to couple the drain electrode of semiconductor die 110 to drain lead 140.

Although the scope of the present invention in not limited in this respect, after wirebonding, the next step in the assembly process may include bending the gate leads and the drain leads of leadframe 200 prior to encapsulation to form J-shaped leads as is illustrated with leads 120 and 140 shown in FIG. 1. Next, all of the semiconductor die and a portion of leadframe 200 may be encapsulated using a molding compound or plastic packaging material to form a unitary structure comprising multiple semiconductor components 200. The molding compound is formed between gate leads 120 and source leads 130 and between source leads 130 and drain leads 140 to electrically isolate the leads of leadframe 200 from each other.

Next, the unitary structure may be singulated into individual semiconductor components using sawing or laser cutting, wherein each individual packaging component includes at least one semiconductor die and wherein each die comprises a radio frequency (RF) power transistor.

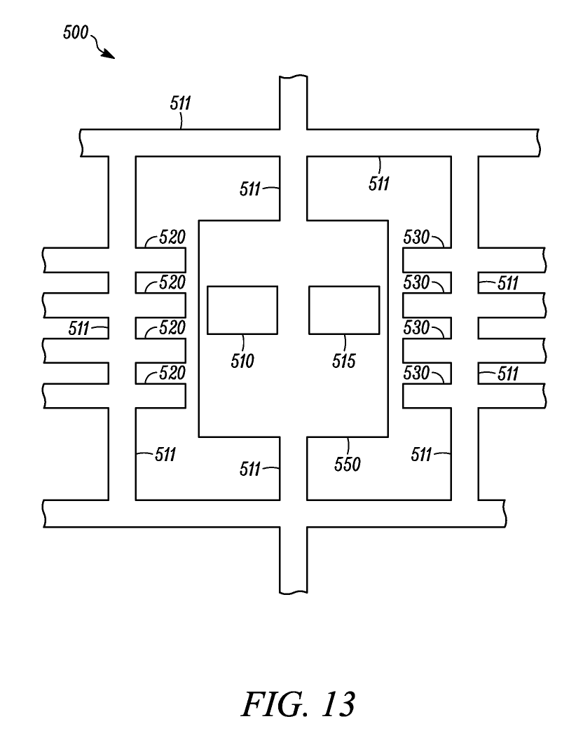

As may be appreciated, in alternate embodiments, the methods and structures discussed above may be used to manufacture a semiconductor component having more than three leads. An embodiment of a semiconductor component having multiple leads using the methods and structures discussed herein is described below with reference to FIG. 13.

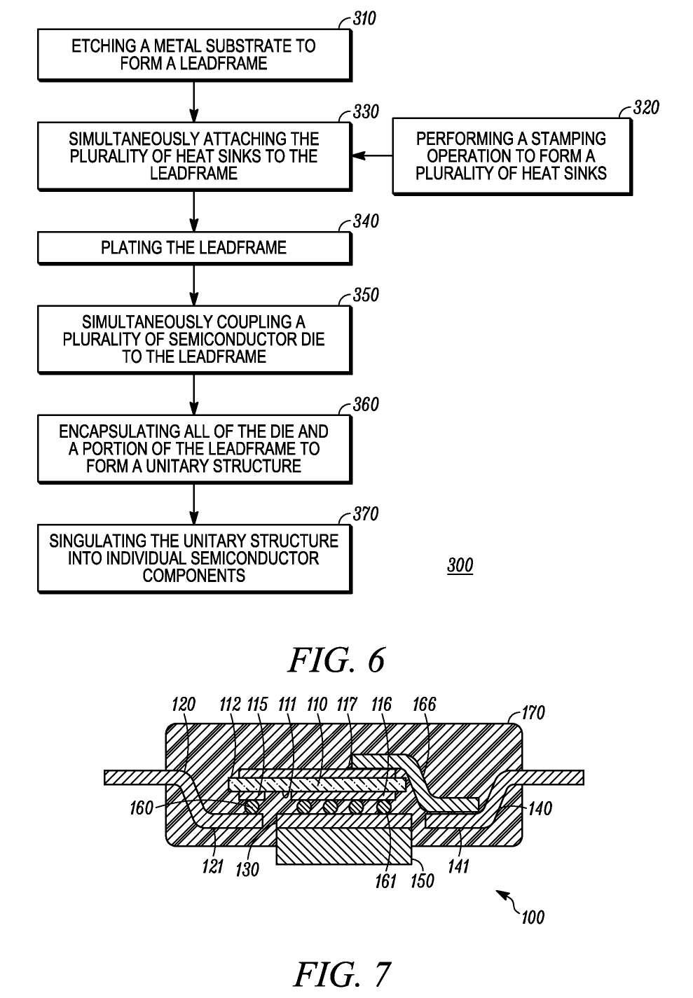

FIG. 6 is a flow diagram of a method 300 to manufacture semiconductor components in accordance with an embodiment of the present invention. Although the individual operations of method 300 are illustrated and described as separate operations, one or more of the individual operations may be performed concurrently and nothing requires that the operations be performed in the order illustrated. Method 300 will be described with reference to FIGS. 1-5 and may be used to manufacture a power transistor.

Method 300 may begin either with etching a metal substrate to form a leadframe 200 (block 310) or performing a stamping operation to form a plurality of heat sinks 200 (block 320). Leadframe 200 may be etched to form a plurality of coplanar, spaced apart leads 120, 130, and 140. Next, method 300 may include simultaneously attaching the plurality of heat sinks 150 to leadframe 200 (block 330).

After attaching the plurality of heat sinks 150 to leadframe 200, leadframe 200 may be plated using, for example, NiPd (block 340) with a “flash” of gold (Au) or silver (Ag), or may be tin (Sn) plated. After plating leadframe 200, a plurality of semiconductor die 110 are simultaneously coupled to leadframe 200 (block 350). Next, all of the semiconductor die 110 and a portion of leadframe 200 is encapsulated using a molding compound to form a unitary structure comprising multiple semiconductor components (block 360). The molding compound is formed between gate leads 120 and source leads 130 and between source leads 130 and drain leads 140 to electrically isolate the leads of leadframe 200 from each other. Next, the unitary structure may be singulated into individual semiconductor components (block 370).

As may be appreciated, method 300 may provide advantages for manufacturing a power transistor compared to serialized assembly methods for manufacturing discrete power transistors. Serialized assembly methods may include forming individual, singulated leads that are not coupled to each other using tie bars. A power transistor may be assembled in a serial fashion using the individual, singulated leads wherein each power transistor is formed one at a time rather than simultaneously assembling multiple power transistors using the methods described above, which include some parallel acts or steps.

Method 300 may result in cost reductions and greater manufacturing efficiencies in the assembly of power transistors by using batch operations to form the leads of a leadframe with tie bars to support the leads and by simultaneously coupling all of the heat sinks and semiconductor die to such a leadframe. Generally, a batch operation may mean an act or action performed on a group of items at one time.

Turning back to FIG. 1, although semiconductor component 100 is illustrated in FIG. 1 as having wafer bumps and wirebonds, this is not a limitation of the present invention. Other techniques may be used to couple portions of semiconductor die 110 to the leads of semiconductor component 100. For example, turning briefly to FIG. 7, a metal clip 166 may be used to couple drain interconnect 117 to drain lead 140. Using a metal clip, rather than wirebonds may further reduce parasitic inductance, thereby improving performance of semiconductor component 100. The embodiment of semiconductor component 100 illustrated in FIG. 7 may be referred to as a component or device devoid of wirebonds.

In addition, fewer or more wafer bumps and wirebonds may be used to couple portions of semiconductor die 110 to leads 120, 130, and 140. Further, interconnects 115 and 116 may be coupled to leads 120 and 130 without wafer bumps. For example, in some embodiments, interconnects 115 and 116 may be coupled to leads 120 and 130 using solder.

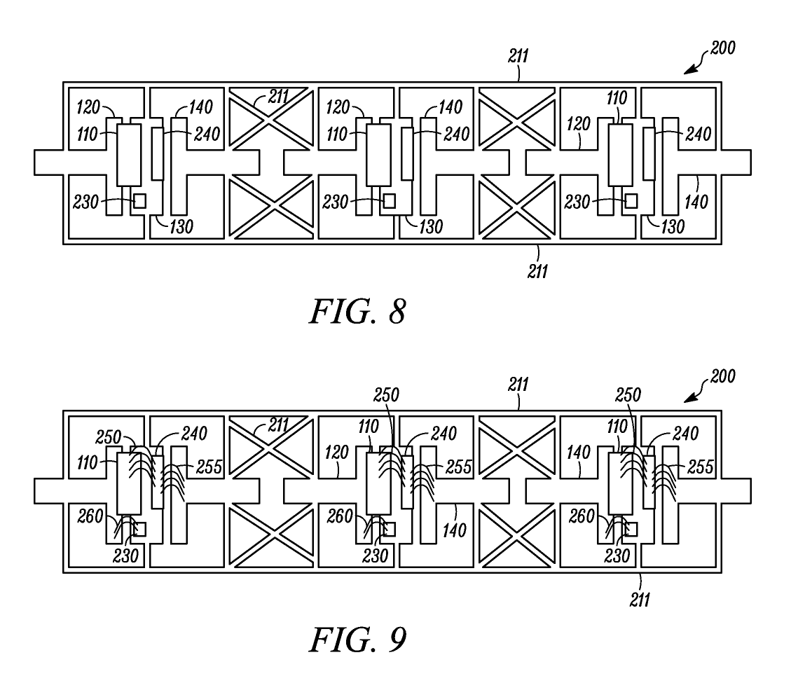

Turning to FIGS. 8 and 9, an alternate embodiment of the present invention is illustrated using some of the methods and structures discussed above. FIGS. 8 and 9 illustrate an alternate embodiment to assemble semiconductor components using leadframe 200 compared to the embodiment illustrated in FIGS. 4 and 5. In particular, FIGS. 8 and 9 illustrate the assembly of integrated circuit (IC) semiconductor components using leadframe 200, wherein the semiconductor components include at least two semiconductor die or at least two discrete circuit elements such as a discrete ESD protection circuit 230 discussed below.

FIG. 8 is a top view of a portion of leadframe 200 during assembly in accordance with an embodiment of the present invention. After coupling the heat sinks 150 to leadframe 200 as was discussed above with reference to FIG. 3, a number of semiconductor die or circuits may be coupled to leadframe 200.

In this embodiment, semiconductor die 110 is coupled to the top surfaces of gate leads 120 and source leads 130. Although the scope of the present invention is not limited in this respect, an electrostatic discharge (ESD) protection circuit 230 and an input/output (I/O) impedance matching network 240 may be mounted on the top surface of source lead 130. Although not shown in the figures, impedance matching network may be comprised of inductors and capacitors.

FIG. 9 is a top view of a portion of leadframe 200 at a later stage of assembly in accordance with an embodiment of the present invention. In some embodiments, one or more wirebonds 250 may be used to connect the drain electrode of semiconductor die 110 to impedance matching network 240. Wirebonds 255 may be used to connect impedance matching network 240 to drain lead 140 and wirebonds 260 may be used to connect ESD protection circuit 230 to gate lead 120.

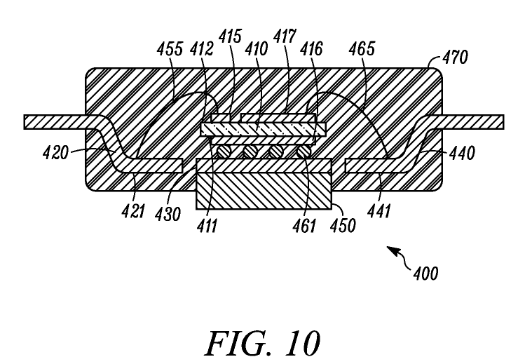

FIG. 10 is a cross-sectional view of a semiconductor component 400 in accordance with an embodiment of the present invention.

In some embodiments, semiconductor component 400 includes a semiconductor die 410, a gate lead 420, a source lead 430, a drain lead 440, and a heat sink 450. Heat sink 450 is coupled to a bottom surface of source lead 430.

Semiconductor die 410 may be coupled to a top surface of source lead 430. Semiconductor die 410 may be an integrated circuit or a discrete FET. In some embodiments, semiconductor die 400 may be discrete power transistor such as, for example, a laterally diffused metal-oxide-semiconductor (LDMOS) power transistor. An LDMOS transistor is a lateral transistor structure, wherein current flows laterally through the transistor between the source and drain regions of the LDMOS power transistor.

Semiconductor die 410 may have surfaces 411 and 412 and may have a gate interconnect 415 on surface 412, a source interconnect 416 on surface 411, and a drain interconnect 417 on surface 412. Interconnects 415, 416, and 417 may be comprise an electrically and thermally conductive material such as, for example, a metal or metal alloy. In some embodiments, interconnects 415, 416, and 417 may comprise copper.

Gate lead 420 is coupled to gate interconnect 415 via a wire bond 455; source lead 430 is coupled to source interconnect 416 via wafer bumps 461; and drain lead 440 is coupled to drain interconnect 417 via a wirebond 465.

Although semiconductor component 200 is illustrated in FIG. 10 as having wafer bumps and wirebonds, this is not a limitation of the present invention. Other techniques may be used to couple portions of semiconductor die 410 to the leads of semiconductor component 400. For example, metal clips (not shown) may be used to couple drain interconnect 417 to drain lead 440 and to couple gate interconnect 415 to gate lead 420. In addition, fewer or more wafer bumps and wirebonds may be used to couple portions of semiconductor die 410 to leads 420, 430, and 440. Further, interconnect 416 may be coupled to lead 430 without wafer bumps.

Semiconductor component 400 may further include a packaging material 470 such as, for example, a plastic packaging material or other organic material such as a glob top material, that encapsulates semiconductor die 410, source lead 430, a portion of gate lead 420, a portion of drain lead 440, and a portion of heat sink 450.

Leads 420, 430, and 440 are electrically isolated from each other by packaging material 470. In the embodiment illustrated in FIG. 10, packaging material 470 is formed between gate lead 420 and source lead 430 and between source lead 430 and drain lead 440.

In some embodiments, the leads of semiconductor component 400 may be formed from the same material so that portions of the leads are substantially coplanar to each other. For example, a portion 421 of gate lead 420 is substantially coplanar to source lead 430 and a portion 441 of drain lead 440 is substantially coplanar to source lead 430.

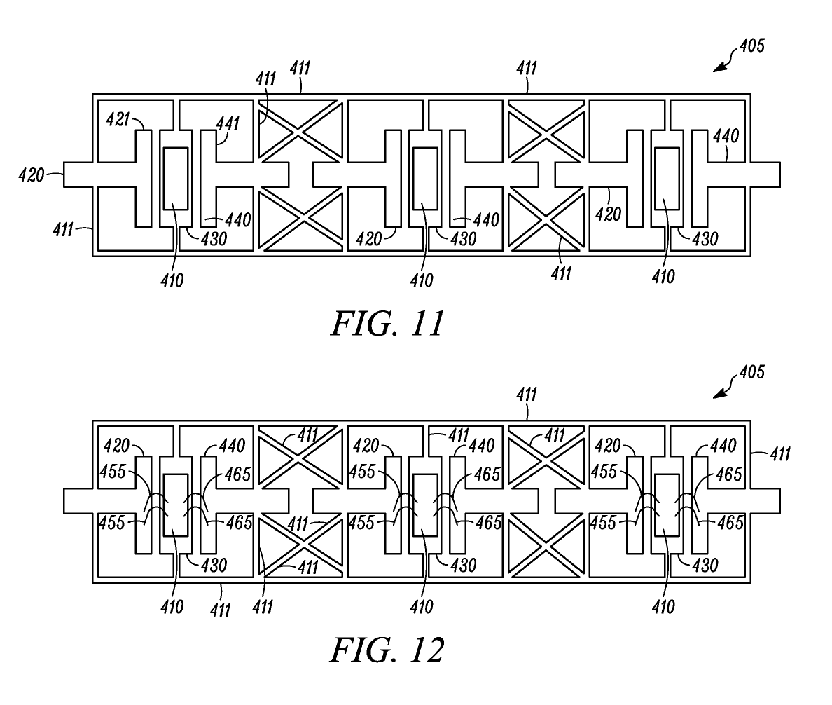

The assembly of semiconductor component 400 is illustrated using FIGS. 10, 11 and 12. FIG. 11 is a top view of a portion of a leadframe 405 during assembly in accordance with an embodiment of the present invention. Leadframe 405 is similar to leadframe 200 described above. For example, leadframe 405 may be formed using similar materials and processes as described above for forming leadframe 200.

Leadframe 405 may be formed by etching an electrically and thermally conductive material, such as, for example, a metal substrate or alloy. In some embodiments, leadframe 405 may comprise copper. Leadframe 405 may include coplanar, spaced apart leads 420, 430 and 440 that are formed at substantially the same time with a single etching step. In addition, leadframe 405 may include a plurality of support structures 411 to couple the leads of leadframe 200 to each other during packaging of multiple semiconductor components. As will be discussed below, in some embodiments, leadframe 405 may be singulated after the encapsulation of multiple semiconductor components.

Although not shown in the figures, heat sinks 450 (FIG. 10) may be coupled to the bottom surfaces of source leads 430 of leadframe 405 at substantially the same time in a single step. The heat sinks 450 may be formed by performing a stamping operation. Prior to the attaching of semiconductor die 410 to leadframe 405, leadframe 405 including the attached heat sinks, may be plated.

A plurality of semiconductor die 410 are coupled to the top surfaces of source leads 430 prior to encapsulating the semiconductor die and a portion of leadframe 405 using a packaging material. Semiconductor die 410 may be attached in a batch operation, or may be attached individually in separate steps at different points in time.

FIG. 12 is a top view of a portion of leadframe 405 at a later stage of assembly in accordance with an embodiment of the present invention. In some embodiments, one or more wirebonds 465 may be used to couple the drain electrode of semiconductor die 410 to drain lead 440 and one or more wirebonds 455 may be used to couple the gate electrode of semiconductor die 410 to gate lead 420.

FIG. 13 is top view of a portion of a leadframe 500 during assembly in accordance with an embodiment of the present invention. Leadframe 500 may be formed using similar materials and processes as described above for forming leadframe 200.

In some embodiments, leadframe 500 may be formed by etching an electrically and thermally conductive material, such as, for example, a metal substrate or alloy.

In some embodiments, leadframe 500 may comprise copper. Leadframe 500 may include coplanar, spaced apart leads 520, 530, and 550 that are formed at substantially the same time with a single etching step. In addition, leadframe 500 may include a plurality of support structures 511 to couple the leads of leadframe 500 to each other during assembly of multiple semiconductor components. As will be discussed below, in some embodiments, leadframe 500 may be singulated after the encapsulation of multiple semiconductor components. Support structures 511 may also be referred to as bars, rails, or tie bars.

Although not shown in the figures, heat sinks may be coupled to the bottom surfaces of leads 550 of leadframe 500 at substantially the same time in a single step. The heat sinks may be formed by performing a stamping operation and may be used for removing heat generated by semiconductor die coupled to lead 550. Prior to the attaching of semiconductor die to leadframe 500, leadframe 500 including the attached heat sinks, may be plated.

Semiconductor die 510 and 515 may be coupled to the top surfaces of leads 550 prior to encapsulating the semiconductor die and a portion of leadframe 500 using a packaging material. Semiconductor die 510 and 515 may be attached in a batch operation, or may be attached individually in separate steps.

In one embodiment, semiconductor die 510 may be a discrete transistor and semiconductor die 515 may be an integrated circuit comprising high density digital logic. Either or both of the semiconductor die may generate heat that may be removed either from the top side or bottom side of the die.

Although not shown, in some embodiments, wirebonds or metal clips may be used to electrically couple portions of semiconductor die 510 and 515 to leads 520 and 530. As may be appreciated, semiconductor components having more than three leads and having multiple die may be manufactured using the structure and methods discussed with reference to FIG. 13. In addition, although the structure in FIG. 13 is illustrated as including two semiconductor die, this is not a limitation of the present invention. In alternate embodiments, semiconductor components including only one die or more than two die may be manufactured using leadframe 500.

Although the invention has been described and illustrated with reference to specific embodiments thereof, it is not intended that the invention be limited to these illustrative embodiments. Those skilled in the art will recognize that modifications and variations can be made without departing from the spirit of the invention. Therefore, it is intended that this invention encompass all such variations and modifications as fall within the scope of the appended claims.

We claim:

1. A semiconductor component, comprising:
a semiconductor die, wherein the semiconductor die comprises a power transistor;
a first lead coupled to the semiconductor die;
a second lead coupled to the semiconductor die;
a third lead coupled to the semiconductor die, wherein a major surface of the first lead is substantially coplanar to a major surface of the second lead and substantially coplanar to a major surface of the third lead; and
a packaging material encapsulating the semiconductor die, wherein the packaging material is formed between the first lead and the second lead and between the second lead and the third lead.

2. The semiconductor component of claim 1, wherein a distance between the gate lead and the source lead is less than about 0.1 millimeters (mm) and a distance between the source lead and the drain lead is less than about 0.1 millimeters (mm).

3. The semiconductor component of claim 1, wherein the first lead is a gate lead coupled to a gate electrode of the semiconductor die, the second lead is a source lead coupled to a source region of the semiconductor die, and the third lead is a drain lead coupled to a drain region of the semiconductor die and wherein at least a portion of the source lead is between at least a portion of the gate lead and at least a portion of the drain lead.

4. The semiconductor component of claim 3, further comprising:
an electrostatic discharge (ESD) protection circuit mounted on a first surface of the source lead; and
an input/output (I/O) impedance matching network mounted on the first surface of the source lead.

5. The semiconductor component of claim 3, further comprising a heat sink, wherein the packaging material is a plastic packaging material that encapsulates the semiconductor die, the second lead, a portion of the first lead, a portion of the third lead, and a portion of the heat sink, wherein the first lead, the second lead, and the third lead are electrically isolated from each other by the packaging material.

6. The semiconductor component of claim 5, wherein the semiconductor die has a first major surface and a second major surface and wherein the semiconductor die includes a first interconnect metal over the first major surface, a second interconnect metal over the first major surface, and a third interconnect metal over the second major surface.

7. The semiconductor component of claim 6, wherein the first lead is coupled to the first interconnect metal via at least one wafer bump, the second lead is coupled to the second interconnect metal via at least one wafer bump, and the third lead is coupled to the third interconnect metal via at least one wirebond.

8. The semiconductor component of claim 7, wherein the heat sink comprises copper, the first lead comprises copper, the second lead comprises copper, the third lead comprises copper, the wafer bumps comprise an electrically and thermally conductive material, and wherein the power transistor is a discrete radio frequency (RF) power transistor adapted to operate at frequencies greater than about 50 MHz and has a power output greater than about 5 watts.

9. The semiconductor component of claim 5, wherein a portion of the first lead is partially exposed external to the semiconductor component to provide electrical coupling of an external bias signal to the gate electrode from an external source, a portion of the second lead is partially exposed external to the semiconductor component to provide electrical coupling of an external bias signal to the drain region from an external source, and the heat sink is partially exposed external to the semiconductor component to provide electrical coupling of an external bias signal to the source region from an external source.

10. The semiconductor component of claim 1,
wherein the semiconductor die has a first major surface and a second major surface and wherein the semiconductor component includes a first interconnect metal over the first major surface, a second interconnect metal over the first major surface and separated from the first interconnect metal, and a third interconnect metal over the second major surface;
wherein the power transistor is a vertical power transistor having a gate coupled to the first interconnect metal, a source region coupled to the second interconnect metal, and a drain region couple to the third interconnect metal; and
wherein the first lead is a gate lead coupled to the first interconnect metal, the second lead is a source lead coupled to the second interconnect metal, and the third lead is a drain lead coupled to the third interconnect metal.

11. The semiconductor component of claim 1, wherein the semiconductor die overlies the first and second leads.

12. The semiconductor component of claim 11, further comprising a heat sink coupled to the second lead, wherein the second lead and the heat sink provide a relatively low resistance thermal path to remove heat generated by the semiconductor die.

13. The semiconductor component of claim 1, wherein the semiconductor component is devoid of wire bonds.

14. The semiconductor component of claim 1, wherein the semiconductor component is a discrete component.

15. The semiconductor component of claim 1, wherein the semiconductor component is an integrated component, wherein the semiconductor die is a first semiconductor die, and further comprising a second semiconductor die coupled to at least the second lead.

16. A method, comprising:
coupling a plurality of heat sinks to a leadframe at substantially the same time; and
coupling a plurality of semiconductor die to the leadframe after coupling the plurality of heat sinks to the leadframe, wherein at least one die of the plurality of semiconductor die comprises a power transistor.

17. The method of claim 16, wherein coupling the plurality of heat sinks to the leadframe comprises coupling the plurality of heat sinks to the leadframe at substantially the same time in a single step.

18. The method of claim 16, wherein coupling the plurality of semiconductor die comprises simultaneously coupling the plurality of semiconductor die to some, but not all of the plurality of leads of the leadframe prior to encapsulating the semiconductor die and a portion of the leadframe using a packaging material.

19. The method of claim 16, further comprising etching a conductive material to form the leadframe, wherein the plurality of leads comprise leads of a first type, leads of a second type, and leads of a third type, wherein all of the plurality of leads of the leadframe are substantially coplanar and spaced apart from each other, and wherein the leadframe comprises tie bars to couple the plurality of leads to each other.

20. The method of claim 19, further comprising encapsulating all of the plurality of semiconductor die and a portion of the leadframe using a molding compound to form a unitary structure comprising a plurality of semiconductor components, wherein the molding compound is formed between the leads of the first type and the leads of the second type and formed between the leads of the second type and the leads of the third type to electrically isolate the plurality of leads from each other.

21. The method of claim 19, further comprising singulating the unitary structure into individual semiconductor components using sawing or laser cutting, wherein each individual packaging component includes at least one semiconductor die and wherein each die of the plurality of semiconductor die comprises a radio frequency (RF) power transistor.

22. The method of claim 19, further comprising forming wirebonds to connect the leads of the third type to bond pads on each of the plurality of semiconductor die and wherein each die of the plurality of semiconductor die comprise a radio frequency (RF) vertical power transistor.

23. A method to manufacture a plurality of semiconductor components, comprising:
attaching a plurality of semiconductor die to a leadframe, wherein at least one die of the plurality of semiconductor die comprises a power transistor;
encapsulating all of the plurality of semiconductor die and a portion of the leadframe using a packaging material to form a unitary structure comprising a plurality of semiconductor components; and
singulating the unitary structure into individual semiconductor components.

24. The method of claim 23, further comprising attaching a plurality of heat sinks to some, but not all of the leads of the leadframe in a batch operation prior to attaching the plurality of semiconductor die to the leadframe, wherein each individual semiconductor component comprises at least one semiconductor die and wherein each of the plurality of semiconductor die comprises a vertical power transistor wherein electrical current flows essentially vertically through the power transistor from a source region of the power transistor to a drain region of the power transistor.

25. The method of claim 24, further comprising etching a metal substrate to form the leadframe, wherein the leadframe comprises a plurality of substantially coplanar, spaced apart leads and a plurality of support structures to couple the plurality of leads to each other during packaging of the plurality of semiconductor components and wherein the singulating the unitary structure includes cutting the support structures to separate the plurality of leads from each other.

26. The method of claim 25, wherein the plurality of leads comprise gate leads, source leads, and drain leads and wherein attaching the plurality of heat sinks comprises attaching the plurality of heat sinks to a first major surface of the source leads of the leadframe and wherein attaching the plurality of semiconductor die to the leadframe comprises attaching the plurality of semiconductor die to a second major surface of the source leads of the leadframe and to a first major surface of the gate leads of the leadframe.

27. The method of claim 26, wherein each individual semiconductor component includes at least one gate lead, at least one source lead, at least one drain lead, at least one heat sink and at least one semiconductor die, wherein for each individual semiconductor component: a portion of the heat sink is exposed external to the semiconductor component, a portion of the gate lead is exposed external to the semiconductor component, and a portion of the drain lead is exposed external to the semiconductor component and the at least one heat sink of each individual semiconductor component is attached to the first major surface of the at least one source lead, a first portion of the at least one semiconductor die is attached to the second major surface of the at least one source lead, a second portion of the at least one semiconductor die is attached to a first major surface of the at least one gate lead.

28. The method of claim 26, wherein the gate and drain leads are substantially the same size and wherein the source leads are larger than the gate and drain leads and further comprising bending the gate leads and the drain leads prior to the encapsulating.

29. The method of claim 24, further comprising performing a stamping operation to form the plurality of heat sinks, wherein the stamping operation comprises stamping an electrically and thermally conductive material to form the plurality of heart sinks and wherein stamping includes forming a burr on a portion of each of the plurality of heat sinks to provide a mold lock to increase pull-out resistance of the plurality of heat sinks after the plurality of heat sinks are molded into the packaging material.

30. The method of claim 24, wherein attaching a plurality of semiconductor die to a leadframe comprises attaching the plurality of semiconductor die to a leadframe at substantially the same time and wherein attaching a plurality of heat sinks to the leadframe comprises brazing the heat sinks to the leadframe using a material comprising copper or silver.

31. The method of claim 24, further comprising plating the leadframe using a conductive material after the attaching of the plurality of heat sinks to the leadframe and prior to the attaching of the plurality of semiconductor die to the leadframe.
